(19) United States
(12) Patent Application Publication
(10) Pub. No.: US 2011/0025353 A1
(43) Pub. Date: Feb. 3, 2011

(54) METHOD FOR INCREASING THE AVAILABILITY OF DISPLACEMENT/POSITION MEASURING SYSTEMS ON THE BASIS OF POTENTIOMETERS WITH A SLIDER TAP

(75) Inventors: Stefan Tabelander, Herford (DE); Thomas Kleegrewe, Minden (DE); Andreas Wahlmann, Meerbeck (DE)

Correspondence Address: BUCHANAN, INGERSOLL & ROONEY PC, POST OFFICE BOX 1404, ALEXANDRIA, VA, 22313-1404, US

(73) Assignee: ABB Technology AG, Zurich (CH)

(21) Appl. No.: 12/842,306

(22) Filed: Jul. 23, 2010

(30) Foreign Application Priority Data
Jul. 29, 2009 (DE) 10 2009 035 126.4

(51) Int. Cl. G01R 27/08

(52) U.S. Cl. 324/714

(57) ABSTRACT

The disclosure relates to a method for increasing the availability of displacement/position measuring systems on the basis of potentiometers with a slider tap in a closed control loop, the controller of which is formed by a microcontroller which is supplied with the position of the slider via an analog/digital converter. The position of a defective slider position of the potentiometer is determined within the active process task by evaluating an available control loop variable, and the reference variable of the control loop is overloaded in a defined manner such that the defective slider position is passed over during the displacement/position measurement and an intact slider position is reached.

### RELATED APPLICATION

This application claims priority under 35 U.S.C. §119 to German Patent Application No. 10 2009 035 126.4 filed in Germany on Jul. 29, 2009, the entire content of which is hereby incorporated by reference in its entirety.

### FIELD

The disclosure relates to a method for increasing the availability of displacement/position measuring systems on the basis of potentiometers with a slider tap.

### BACKGROUND INFORMATION

Position measuring systems are used, for example, in electropneumatic position controllers and electrical variable-speed drives to return an actual value and are thus part of a closed control loop. The sudden failure of the position measuring system can result in the immediate failure of the device functionality.

The structure and method of operation of a closed control loop are generally known and are described, for example, at http://de.wikipedia.org/wiki/Regelkreis, extracts of which are shown in FIG. 1.

The product brochure “Der kompakte, intelligente Stellungsregler” (The compact, intelligent position controller), ABB Automation Products GmbH, print number: 50/18-19 DE RevA; June 2005 edition, discloses an electronic position controller for a pneumatic actuator.

In such a position controller and with reference to FIG. 1, the reference variable w can be preset via a desired value channel formed, in particular, by an analog 4.20 mA input or a field bus such as HART, Profibus PA, Foundation field bus, etc.

In this arrangement, the control path F_{S} forms the pneumatic actuator/variable-speed drive to be positioned. In the known position controller, the control element F_{R}, the actuating element F_{St} and the measuring element F_{M} can be constructed in a housing. In the known actuator, the control element F_{R} can be in the form of a microcontroller-supported system. In the known actuator, the measuring element F_{M} can be in the form of a potentiometer with a slider tap which measures the set position x of the drive to be controlled. The actuating element F_{St} can typically be in the form of an IP module in an electropneumatic position controller.

In this case, the potentiometer can be supplied with a constant and known reference voltage, and the position can then be detected in an analog/digital converter using the displacement-proportional voltage tap. In terms of circuitry, this arrangement can thus be in the form of a voltage divider with a position-dependent voltage tap. The feedback variable r can be present in digital form in the analog/digital converter. The voltage tap can be effected with the highest possible impedance of the measuring circuit in order to minimize measurement errors.

The microcontroller-supported system can form a controller output variable yᵣ from the control difference e with the aid of a suitable control algorithm in the controller F_{R}, which output variable can be used to drive the IP module via a suitable electronic circuit.

In some special applications, the position sensor belonging to the position measuring system as well as other associated components are not arranged in the same housing. In this case, the position measuring system can be arranged outside the positioner as a remote displacement sensor.

Potentiometers with a slider tap have the property that they are resistant to vibrations only to a limited extent. In addition, the slider and the resistance track wear away as a result of electrical erosion after a finite number of movements until they become defective.

In the case of a frequently occurring error pattern, the resistance track can be damaged by abrasion and/or electrical erosion as a result of a slider which cyclically oscillates around a constantly recurring point since the position controller corrects only small control errors. This occurs, in particular, in feedback systems, as can be found in electropneumatic position controllers or electrical variable-speed drives, when they operate with a constant or virtually constant desired value for a long period of time. A defect can be fostered by poor controllability of the control path because the latter tends toward the oscillation, the period of time for which control is effected at a constant or virtually constant desired value because the associated sensor/potentiometer range is then used for a long time, and the occurrence of a defect can increase as the frequency increases.

Only a range of a few angular degrees is often affected. In this case, the slider works its way ever further into the material of the resistance track until it finally can no longer make contact. The potentiometer is worn at this point and therefore cannot continue to be used for measurement. More than one point of the sensor may be defective inside an operating range.

In addition, chemical influences have a negative effect on the service life of slider potentiometers. A defect of the potentiometer can result in the failure of the displacement/position measurement.

The failure of the displacement/position measuring system can disadvantageously result in the failure of the device function, as a result of which the position controller carries out a positioning reaction which is predetermined for the controller and in which the controller remains until the cause of the failure has been rectified. Positioning reactions which can be carried out without a displacement/position measuring system can be preset for this purpose. Depending on the respective application, provision may be made to ventilate or vent the drive, so-called “fail safe”, or to block the drive in the current position, so called “fail freeze.”

Because failure typically cannot be predicted and is also not diagnosed at regular service intervals, such failure results in unplanned stopping of the process which is often associated with high costs for the user.

In the attempt to increase the availability of the sensor, contactless measuring methods, as are revealed in DE 42 39 635 A1 and DE 10 2007 019 045 A1 for example, have been investigated. However, it has been found that these methods, with a higher degree of technical complexity than potentiometer-based measurement, also have such a high energy consumption that they are rendered unusable for applications in devices which are supplied from a current loop whose power is limited.

### SUMMARY

A method is disclosed for increasing the availability of displacement/position measuring systems on the basis of potentiometers with a slider tap in a closed control loop, the controller of which is formed by a microcontroller. The method includes supplying the microcontroller with the position of the slider via an analog/digital converter, determining the exact position of a defective slider position of the potentiometer within an active process task by evaluating an available control loop variable, overloading the reference variable of the control loop in a defined manner such that the defective slider position is avoided during the displacement/position measurement and reaching an intact slider position.

### BRIEF DESCRIPTION OF THE DRAWINGS

The disclosure is explained in more detail below using exemplary embodiments. In the drawings:

FIG. 1 shows a basic illustration of a known control loop;

FIG. 2 shows a basic illustration of an exemplary embodiment of an actuator having a potentiometer-based device for determining the position;

FIG. 3 shows a basic illustration of a exemplary embodiment of an control loop according to the disclosure; and

FIG. 4 shows an illustration of a characteristic curve.

### DETAILED DESCRIPTION

The features of the disclosure can increase the availability of a potentiometer-based displacement/position measuring system whilst retaining the measurement principles.

An exemplary embodiment according to the disclosure can be based on a displacement/position measuring system on the basis of potentiometers with a slider tap in a closed control loop, the controller of which can be formed by a microcontroller which can be supplied with the position of the slider via an analog/digital converter. In such a potentiometer a “buried” slider does not interrupt the resistance track but rather only the tap is no longer possible at this singular, eroded position.

According to the disclosure, the exact position of a defective slider position of the potentiometer can be determined within the active process task by evaluating an available control loop variable, and the reference variable of the control loop can be overloaded in a defined manner in the range of the defective position such that the defective slider position can be avoided during the displacement/position measurement and an intact slider position can be reached.

In this case, the actuating element can be positioned in a defined manner with respect to the desired value preset. During positioning, the defective slider position is only dynamically passed over during the positioning operation but is no longer statically approached.

In addition, a superordinate device can be warned of the detection of a defective slider position.

In favor of greater availability, a temporary reduction in the positioning accuracy can be accepted. However, the total failure of the device function can be avoided in this case.

In the case of a displacement/position measuring system with an analog/digital converter, a defective slider position can be detected as an invalid numerical value of the digital output in the operating range of the potentiometer. When starting up the device, the entire operating range within the measurement range of the potentiometer can be scanned at least once. The limits of the operating range in the respective application can then be known. At a defective slider position, the partial voltage tapped off across the slider is outside the limits of the operating range determined during start-up.

According to another exemplary embodiment of the disclosure, a defective slider position can be detected by unexpected deviations, such as severe discontinuities, sudden changes or severe changes, between a plurality of measured values in comparison with an expected characteristic curve profile of the partial voltage across the slider of the potentiometer. The transfer characteristic of a potentiometer can be linear. Deviations from the expected linearity can be detected in a simple manner.

According to another exemplary embodiment of the disclosure, the deviation from the expected profile can be specifically detected by comparing the actual profile with a reference which can be stored in a nonvolatile manner.

According to another exemplary embodiment of the disclosure, a defective slider position of the sensor can be assumed to be detected only when at least a predefinable significant quantity of a minimum number of connected measurements provides an indicator. The measured values detected as being incorrect can be replaced with valid replacement values. The valid replacement values may be formed from the average values of the remaining measured values or from the last usable measured values. However, other methods which use an intelligent observer are also conceivable.

Another exemplary embodiment of the disclosure provides for the determination and the knowledge of the sufficiently accurate location of a defective slider position to be effected or at least assisted by the fact that individual insignificant quantities of faulty measurements within a minimum number of connected measurements, which do not alone lead to the interpretation of a defect, can be analyzed at the run time in such a manner that the valid measured values surrounding the incorrect measured value within the minimum number of connected measurements can be stored and are used to obtain the information for a defective sensor position gradually and/or in a subsequent decision step.

In this case, the location of a defective slider position can be determined in a sufficiently accurate manner by the fact that, after a defined number of faulty measurements which are not necessarily connected but always occur around the same point, the location of this point can be assumed to be a defective sensor position.

According to an exemplary embodiment of the disclosure, the location of a defective slider position can be determined as an assignment to the feedback variable, the last valid values of the feedback variable being known to the system and being used to determine the location directly or indirectly as an estimate with knowledge of other state and/or past factors. In this case, provision may be specifically made to collect n+m values in a ring memory. If n values are invalid, the m remaining values show the sufficiently accurate location in the sensor range. This assumption of the location can also be improved using a state/observer mechanism.

According to an exemplary embodiment of the disclosure, the location of a defective slider position can be determined by assigning the current reference variable to the feedback variable. In this case, it is desirable if the system is in a corrected state and no new desired value preset as a result of a changed reference variable follows. In the corrected state, a zone known to the system is not left.

According to another exemplary embodiment of the disclosure, the sensor range can at least partially be subdivided into segments of a known size and, when a defective sensor position is determined, at least that segment in which the defect is present can be excluded from control such that arbitrary desired value presets do not give rise to any reference variables which allow the system to permanently operate in that segment of the sensor which has been detected as being defective. Specifically, the affected segment can be excluded in that manner in this case, sporadic operation in the defective range not resulting in failure of the system.

In another exemplary embodiment of the disclosure, the reference variable as the result of a desired value preset, which would be caused by operation in a range excluded as being defective, can be rounded up or down in such a manner that the controller operates with the smallest possible control error at the upper or lower limit value with a sufficient distance from the excluded range.

According to another exemplary embodiment of the disclosure, a diagnostic message can be generated in response to the detection of a range affected by at least one defect and can be transmitted to a superordinate device which includes information relating to the location of the defective range, the size and the number of defective positions.

According to exemplary embodiment of the disclosure, the size of at least one coherently excluded range can be used as a criterion for the failure of the entire measuring system.

According to an exemplary embodiment of the disclosure, the number of ranges excluded in the measurement range used can be used as a criterion for the failure of the entire measuring system.

According to an exemplary embodiment of the disclosure, the absolute size of all excluded ranges can be used as a criterion for the failure of the entire measuring system.

According to an exemplary embodiment of the disclosure, the occurrence of connected defective position measurements in response to a sudden change in the desired value can be used as a criterion for the failure of the entire measuring system. As an alternative to the detection of a sudden change in the desired value, it is also possible to use an item of speed information to detect a movement. In the case of an attenuated desired value preset, as occurs in a typical ramp function, exclusion is intended to be carried out.

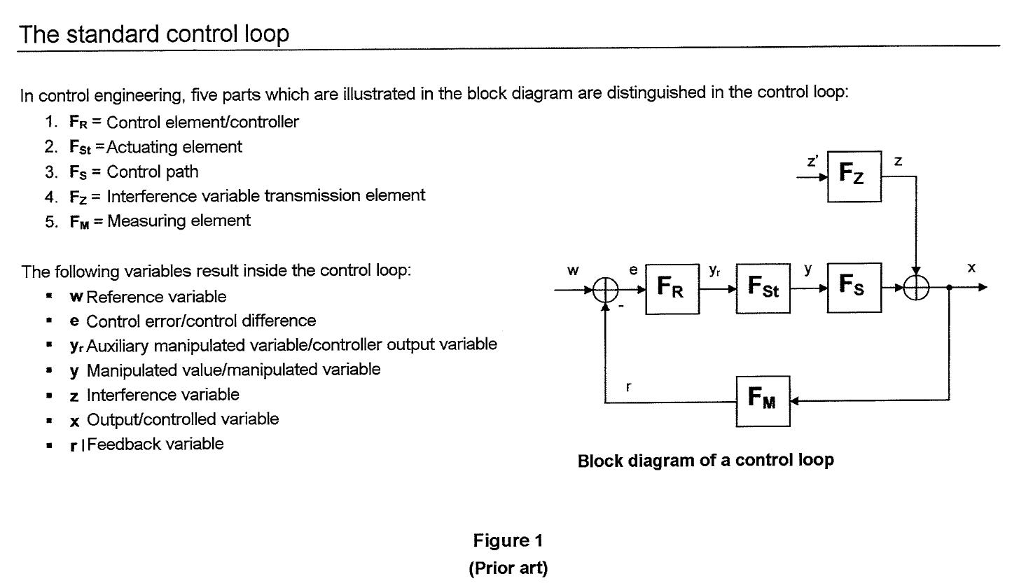

FIG. 1 shows the basic structure of a control loop which emerges from the prior art, which structure has already been explained in the introductory part of the description.

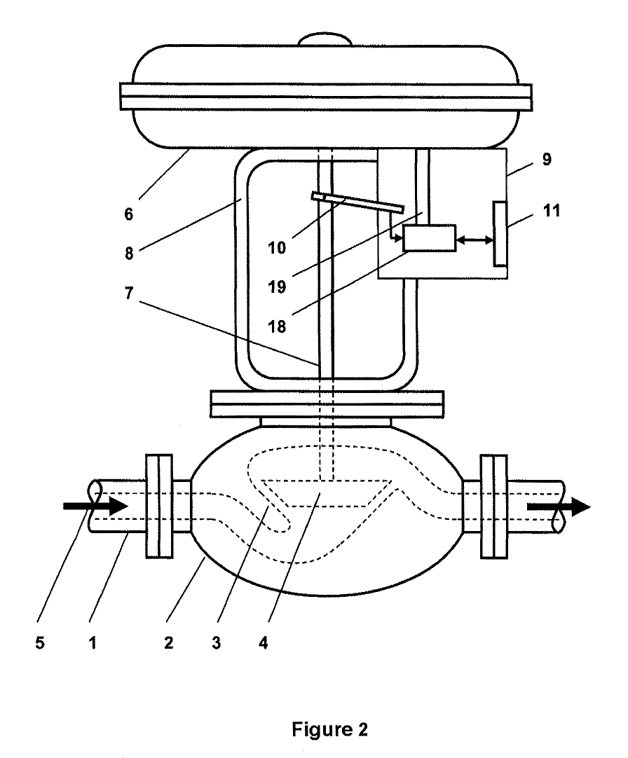

In FIG. 2, a process valve 2 is installed, as an actuating element, in a pipeline 1, which is indicated in fragmentary form, of a process installation which is not illustrated in any more detail. In its interior, the process valve 2 has a closing body 4 which interacts with a valve seat 3 and can control the amount of process medium 5 passing through. The closing body 4 can be linearly operated, via a lifting rod 7, by a pneumatic actuator 6. The actuator 6 is connected to the process valve 2 via a yoke 8. A digital position controller 9 is fitted to the yoke 8. The travel of the lifting rod 7 can be reported to the position controller 9 via a position sensor 10. The travel detected can be compared with the desired value, which can be supplied via a communication interface 11, in control electronics 18, and the actuator 6 can be driven on the basis of the control error determined. The control electronics 18 of the position controller 9 operate an I/P converter for converting an electrical control error into an adequate control pressure. The I/P converter of the position controller 9 can be connected to the actuator 6 via a pressure medium supply 19.

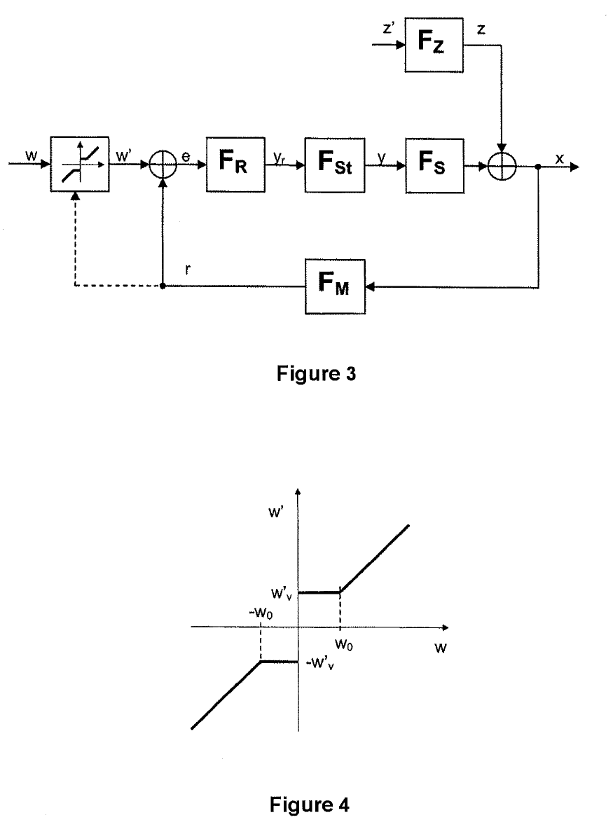

The position sensor 10 can be connected to the axis of rotation of a potentiometer in the position controller 9 and has an eye in which a catch on the lifting rod 7 engages. This potentiometer can be part of the measuring element F_{M} in the control loop according to FIG. 1 and, at the same time, in the extended control loop according to FIG. 3 which is explained below.

FIG. 3 shows a basic illustration of a control loop which has been extended according to the disclosure. In this case, the functional chain starting with the control error e, via the controller F_{R}, the actuating element F_{St}, the control path F_{S} and the measuring element F_{M}, to the feedback variable r corresponds to the known control loop according to FIG. 1.

Unlike the known control loop, the reference variable w can be overloaded with a modified reference variable w′ which can be combined with the feedback variable r in a manner known per se to form the control error e. In this case, the modified reference variable w′ can be formed by deliberately rounding the reference variable w up or down in such a manner that the system passes over or remains in front of the sensor range which has been detected as being defective and has been declared as such and which would be approached by the reference variable w without the overloading operation.

A transfer characteristic from the reference variable w to the modified reference variable w′ is illustrated in FIG. 4. For all values of the reference variable w outside the range −w₀ to w₀ which extends symmetrically around the coordinate origin, the modified reference variable w′ is equal to the reference variable w. Within the range −w₀ to w₀, the modified reference variable w′ can be formed by a positive preset value w′ᵥ for positive values of the reference variable w and can be formed by a negative preset value −w′ᵥ for negative values of the reference variable w. As a result, the range −w₀ to w₀ of the reference variable w can be removed from the range of values of the modified reference variable w′.

Based on the transfer characteristic according to FIG. 4, each defective slider position from the feedback variable r is respectively projected per se onto the coordinate origin of the transfer function of the reference variable w to w′. As soon as the actuator 6 approaches a defective slider position on account of its reference variable w and thus approximates the feedback variable r declared as being defective, the preset value w′ᵥ can be output as a modified reference variable w′ for positive values of the reference variable w and the preset value −w′ᵥ can be output as a modified reference variable w′ for negative values of the reference variable w upon entering the range −w₀ to w₀. Combining the modified reference variable w′ with the feedback variable r provides a control difference e which is relevant to further control, avoids the defective slider position as an intended actual value and instead strives for a defined incorrect position of the process valve 2 at an intact slider position of the potentiometer away from the slider position which has been detected as being defective. As a result, the actuator 6 remains usable until the requested replacement of the potentiometer.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE SYMBOLS

1 Pipeline
2 Process valve
3 Valve seat
4 Closing body
5 Process medium
6 Actuator
7 Valve rod
8 Yoke
9 Position controller
10 Position sensor
11 Communication interface
18 Control electronics
19 Pressure medium supply

What is claimed is:

1. A method for increasing the availability of displacement/position measuring systems on the basis of potentiometers with a slider tap in a closed control loop, the controller of which is formed by a microcontroller, the method comprising:
supplying the microcontroller with the position of the slider via an analog/digital converter;
determining the exact position of a defective slider position of the potentiometer within an active process task by evaluating an available control loop variable;
overloading the reference variable of the control loop in a defined manner such that the defective slider position is avoided during the displacement/position measurement; and
reaching an intact slider position.

2. The method as claimed in claim 1, comprising:
detecting a defective slider position as an invalid numerical value of the digital output in the operating range of the potentiometer.

3. The method as claimed in claim 1, comprising:
detecting a defective slider position by unexpected deviations, such as severe discontinuities, sudden changes or severe changes, between a plurality of measured values in comparison with an expected characteristic curve profile of the partial voltage across the slider of the potentiometer.

4. The method as claimed in claim 3, comprising:
detecting the deviation from the expected profile by comparing the actual profile with a reference which is stored in a nonvolatile manner.

5. The method as claimed in claim 1, comprising:
subjecting the potentiometer to predictive diagnosis in response to the detection of a defective slider position.

6. The method as claimed in claim 1, comprising:
assuming a defective slider position of the sensor is detected only when at least a predefinable significant quantity of a minimum number of connected measurements provides an indicator.

7. The method as claimed in claim 1, comprising:
analyzing a plurality of individual insignificant faulty measurements within a minimum number of connected measurements, which do not alone lead to the interpretation of a defect, at a run time in such a manner that valid measured values surrounding the faulty measured values within the minimum number of connected measurements are stored and are used to obtain the information for a defective sensor position gradually and/or in a subsequent decision step.

8. The method as claimed in claim 7, comprising:
determining the location of a defective slider position in a sufficiently accurate manner by the fact that, after a defined number of faulty measurements which are not necessarily connected but always occur around the same point, the location of this point is assumed to be a defective sensor position.

9. The method as claimed in claim 1,
determining the location of a defective slider position as an assignment to the feedback variable, the last valid values of the feedback variable being known to the system and being used to determine the location as an estimate with knowledge of other state and/or past factors.

10. The method as claimed in claim 1,
determining the location of a defective slider position by assigning the current reference variable to the feedback variable.

11. The method as claimed in claim 1, comprising:
at least partially subdividing the sensor range into segments of a known size and, when a defective sensor position is determined, at least that segment in which the defect is present is excluded from control.

12. The method as claimed in claim 11, comprising:
rounding up or down the reference variable as the result of a desired value preset, which would be caused by operation in a range excluded as being defective in such a manner that the controller operates with the smallest possible control error at the upper or lower limit value with a sufficient distance from the excluded range.

13. The method as claimed in claim 1, comprising:
generating a diagnostic message in response to the detection of a range affected by at least one defect and is transmitted to a superordinate device.

14. The method as claimed in claim 1, comprising:
using the size of at least one coherently excluded range as a criterion for the failure of the entire measuring system.

15. The method as claimed in claim 1, comprising:
using the number of ranges excluded in the measurement range used as a criterion for the failure of the entire measuring system.

16. The method as claimed in claim 1, comprising:
using the absolute size of all excluded ranges as a criterion for the failure of the entire measuring system.

17. The method as claimed in claim 1, comprising:
using the occurrence of connected defective position measurements in response to a sudden change in the desired value as a criterion for the failure of the entire measuring system.

18. The method as claimed in claim 2, comprising:
analyzing a plurality of individual insignificant faulty measurements within a minimum number of connected measurements, which do not alone lead to the interpretation of a defect, at a run time in such a manner that valid measured values surrounding the faulty measured values within the minimum number of connected measurements are stored and are used to obtain the information for a defective sensor position gradually and/or in a subsequent decision step.

19. The method as claimed in claim 3, comprising:
analyzing a plurality of individual insignificant faulty measurements within a minimum number of connected measurements, which do not alone lead to the interpretation of a defect, at a run time in such a manner that valid measured values surrounding the faulty measured values within the minimum number of connected measurements are stored and are used to obtain the information for a defective sensor position gradually and/or in a subsequent decision step.

20. The method as claimed in claim 4, comprising:
analyzing a plurality of individual insignificant faulty measurements within a minimum number of connected measurements, which do not alone lead to the interpretation of a defect, at a run time in such a manner that valid measured values surrounding the faulty measured values within the minimum number of connected measurements are stored and are used to obtain the information for a defective sensor position gradually and/or in a subsequent decision step.
